(19) United States
(12) Patent Application Publication
(10) Pub. No.: US 2016/0192488 A1
(43) Pub. Date: Jun. 30, 2016

(54) CIRCUIT BOARD, MULTILAYERED SUBSTRATE HAVING THE CIRCUIT BOARD AND METHOD OF MANUFACTURING THE CIRCUIT BOARD

(71) Applicant: SAMSUNG ELECTRO-MECHANICS CO., LTD., Suwon-si (KR)

(72) Inventors: Tae-Hong MIN, Hwaseong-si (KR); Myung-Sam KANG, Hwaseong-si (KR); Jung-Han LEE, Seoul (KR); Young-Gwan KO, Seoul (KR)

(73) Assignee: SAMSUNG ELECTRO-MECHANICS CO., LTD., Suwon-si (KR)

(21) Appl. No.: 14/962,428

(22) Filed: Dec. 8, 2015

(30) Foreign Application Priority Data
Dec. 30, 2014 (KR) 10-2014-0193247

(51) Int. Cl. H05K 1/11; H05K 3/00; H05K 1/02

(52) U.S. Cl. CPC H05K 1/115; H05K 1/0212; H05K 3/0017; H05K 3/0047; H05K 2201/09854; H05K 2201/10378

(57) ABSTRACT

Disclosed is a circuit board that includes a core portion having a first via disposed therein in the general shape of an hourglass. The circuit board implements a finer via that penetrates a core and improves heat dissipation performance. The circuit board includes a core portion including a first core and a second core made of a metallic material, the first core and the second core being disposed adjacent to each other, and a first via penetrating the core portion.

### CROSS-REFERENCE TO RELATED APPLICATION(S)

This application claims the benefit under 35 USC §119(a) of Korean Patent Application No. 10-2014-0193247, filed on Dec. 30, 2014 with the Korean Intellectual Property Office, the entire disclosure of which is incorporated herein by reference for all purposes.

### BACKGROUND

1. Field

The following description relates to a circuit board.

2. Description of Related Art

Electronic devices have increasingly become lighter, smaller and faster with more functions and higher performances as technologies are developed where a plurality of wiring layers are formed on a printed circuit board (PCB). Technologies have been developed to mount electronic components, for example, active devices or passive devices, on a circuit board in such electronic devices.

A problem with the circuit boards that have become increasingly slimmer is warpage of the board. Warpage is caused because of the thin size of the circuit boards and because the circuit boards are made with various materials having different coefficients of thermal expansion.

Moreover, as application processors (AP) connected to the circuit boards have been equipped with more functions and higher performances, there has been a significantly increased heat generation. Accordingly, there have been efforts to reduce the heat generation or improve heat-dissipating properties.

Furthermore, the application processors and other active devices that continue to become smaller require not only a higher degree of integration but also finer pitches between external connection terminals of these active devices. As a result, there have been growing demands for reduced pitches and increased degree of integration of contact pads, wiring patterns and vias that are provided in the circuit board on which the active devices are mounted.

The related arts of the present invention are disclosed in US 2012-0006469 A1 and KR 10-2010-0138209 A1. All documents cited in the present disclosure, including published documents, patent applications, and patents, may be incorporated herein in their entirety by reference in the same manner as when each cited document is separately and specifically incorporated or incorporated in its entirety.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, there is provided a circuit board for improved heat dissipating performance and reduced warpage.

In another general aspect, there is provided an improved heat dissipating performance while allowing for a fine via that penetrates a via.

In another general aspect, there is provided a circuit board or a multilayered substrate to be manufactured efficiently.

In another general aspect, there is provided circuit board including a core portion including a first core and a second core made of a metallic material, the first core and the second core being disposed adjacent to each other, and a first via penetrating the core portion.

The first via may be formed in the shape of an hourglass.

The core portion may further include an insulation core made of an insulation material, and wherein the first core is disposed on a first surface of the insulation core, and the second core is disposed on a second surface of the insulation core.

The a rate of change of diameter of the first via may increase as the first via penetrates the first core, may remain constant as the first via penetrates the insulation core, and may decrease as the first via penetrates the second core.

The insulation core may be made of graphite or graphene.

The circuit board may including a heat dissipation pass penetrating the insulation core and connecting the first core with the second core.

An insulation film may be disposed on an interface between the core portion and the first via.

The circuit board may including a second via penetrating the insulation film and being in contact with a surface of the core portion.

An electric signal may pass through the first via and a heat may pass through the second via.

The core portion may include an insulation core interposed between the first core and the second core and made of an insulation material, a first additional core made of a different metallic material from that of the first core and the second core and disposed on a surface of the first core, and a second additional core made of a different metallic material from that of the first core and the second core and disposed on a surface of the second core.

A step difference may be formed at an interface of the first core and the first additional core.

The first core and the second core may be made of invar, and the first additional core and the second additional core may be made of copper.

The circuit board may include a through-hole penetrating the core portion and filled with insulation resin, and a fourth via penetrating the insulation resin.

In another general aspect, there is provided a circuit board including a first core made of a first metallic material, a second core made of a different metallic material from the first metallic material and having a surface in contact with a first surface of the first core, a third core made of a different metallic material from the first metallic material and having a surface in contact with the a second surface of the first core, and a first via penetrating from a surface of the second core not in contact with the first core to a surface of the third core not in contact with the first core.

A hole may penetrate the first core, and a material of the second core or the third core may be filled in the hole.

An insulation film may be formed to separate the first, second and third cores from the first via.

The circuit board may include a through-hole penetrating from a surface opposing the surface of the second core to a surface opposing the surface of the third core and having insulation resin filled therein, and a fourth via penetrating the insulation resin inside the through-hole.

The first core may be made of invar, and the second core and the third core may be made of copper.

In another general aspect, there is provided a circuit board including a first core made of a first metallic material, a second core made of a different metallic material from the first metallic material and having the a surface in contact with a first surface of the first core, a third core made of a different metallic material from the first metallic material and having a surface in contact with a second surface of the first core, a fourth core made of the first metallic material and having a surface in contact with a surface opposing the surface of the second core, a fifth core made of the first metallic material and having a surface in contact with a surface opposing the surface of the third core, and a first via penetrating from a surface of the fourth core not in contact with the second core to a surface of the fifth core not in contact with the third core.

A hole may penetrate the first core, and a material of the second core or the third core may be filled in the hole.

An insulation film may be formed to separate the first, second, third, fourth and fifth cores from the first via.

The circuit board may include a through-hole penetrating from the a surface opposing the surface of the fourth core to a surface opposing other surface of the fifth core and having insulation resin filled therein, and a fourth via penetrating the insulation resin inside the through-hole.

In another general aspect, there is provided a method of manufacturing a circuit board may including providing the core portion, etching the core portion from one surface toward the other surface, and etching the core portion from the other surface toward the one surface thereof.

The core portion may include an insulation core, and the insulation core may be drilled.

In another general aspect, there is provided a multilayered substrate including a circuit board, and an electronic component disposed above the circuit board and being connected to at least the first via.

The multilayered substrate may including an interposer being connected to the circuit board and disposed above the electronic component.

The interposer may include a heat transferring structure made of a thermally conductive material.

A capacitor may be embedded in the interposer.

The interposer may have a same structure as that of the circuit board.

The multilayered substrate may include an interposer having a recess, the recess having at least a portion of the electronic component inserted therein.

The multilayered substrate may include a through-via penetrating a core portion of the interposer, wherein a distance from a bottom surface of the through-via to a top surface of the circuit board may be shorter than a distance from a top surface of the electronic component to the top surface of the circuit board.

Other features and aspects will be apparent from the following detailed description, the drawings, and the claims.

### BRIEF DESCRIPTION OF DRAWINGS

FIG. 1 is a diagram illustrating an example of a multilayered substrate.

FIG. 2 is a diagram illustrating an example of a circuit board.

FIG. 3 is a diagram illustrating an example of a core portion.

FIG. 4 is a diagram illustrating an example of a core portion.

FIG. 5 is a diagram illustrating an example of a core portion.

FIG. 6 is a diagram illustrating an example of a core portion.

FIG. 7 and FIG. 8 are diagrams illustrating examples of processes of forming the core portion.

FIG. 9 is a diagram illustrating an example of a method of manufacturing a circuit board.

FIG. 10 is a diagram illustrating an example of modularization for unilateral manufacture of a plurality of circuit boards.

FIG. 11 is a diagram illustrating an example of a circuit board.

FIG. 12 is a diagram illustrating an example of a circuit board.

FIG. 13 is a diagram illustrating an example of some of the processes of manufacturing the circuit board shown in FIG. 12.

FIG. 14 is a diagram illustrating an example of a circuit board.

FIG. 15 is a diagram illustrating an example of some of the processes of manufacturing the circuit board shown in FIG. 14.

FIG. 16 is a diagram illustrating an example of a multilayered substrate.

FIG. 17 is a diagram illustrating an example of a multilayered substrate.

FIG. 18 is a diagram illustrating an example of a multilayered substrate.

Throughout the drawings and the detailed description, unless otherwise described or provided, the same drawing reference numerals refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the systems, apparatuses and/or methods described herein will be apparent to one of ordinary skill in the art. The progression of processing steps and/or operations is described as an example; the sequence of operations is not limited to that set forth herein and may be changed as is known in the art, with the exception of steps and/or operations that necessarily occur in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure is thorough, complete, and conveys the full scope of the disclosure to one of ordinary skill in the art.

Terms such as “first,” “second,” “third” and “fourth” may be used in the description and the claims for distinguishing similar elements from one another and for, although not necessarily so, describing a specific sequence or order of generation. It shall be appreciated, however, that these terms may be compatibly used for description of other sequences than the sequence described herein under a proper environment. Similarly, in the case where a method is described herein to include a series of steps, the order of the steps is not necessarily the order in which these steps are carried out, and a certain step described herein may be skipped, and/or a certain step that is not described herein may be added to the method.

Terms such as “left,” “right,” “front,” “behind,” “top,” “bottom,” “above,” “below,” etc. are used in the description and the claims for the purpose of description only and are not necessarily used for defining invariable relative positions. It shall be appreciated that these terms may be compatibly used for description of other orientations than the orientations described herein under a proper environment. Terms used in the effect of being “connected” shall be used to define a connection in an electrical or non-electrical fashion, either directly or indirectly. Any objects described as being “adjacent” to one another may be properly in physical contact with, in proximity to, or in a same general range or region of one another. In this specification, although not necessarily so, the expression “in an embodiment” may be used to refer to the identical embodiment.

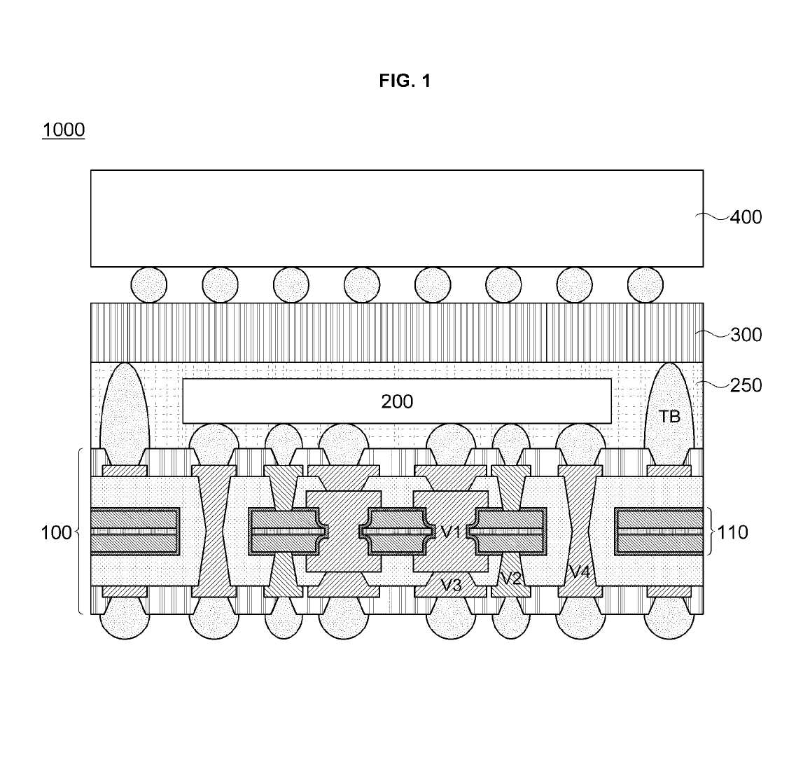

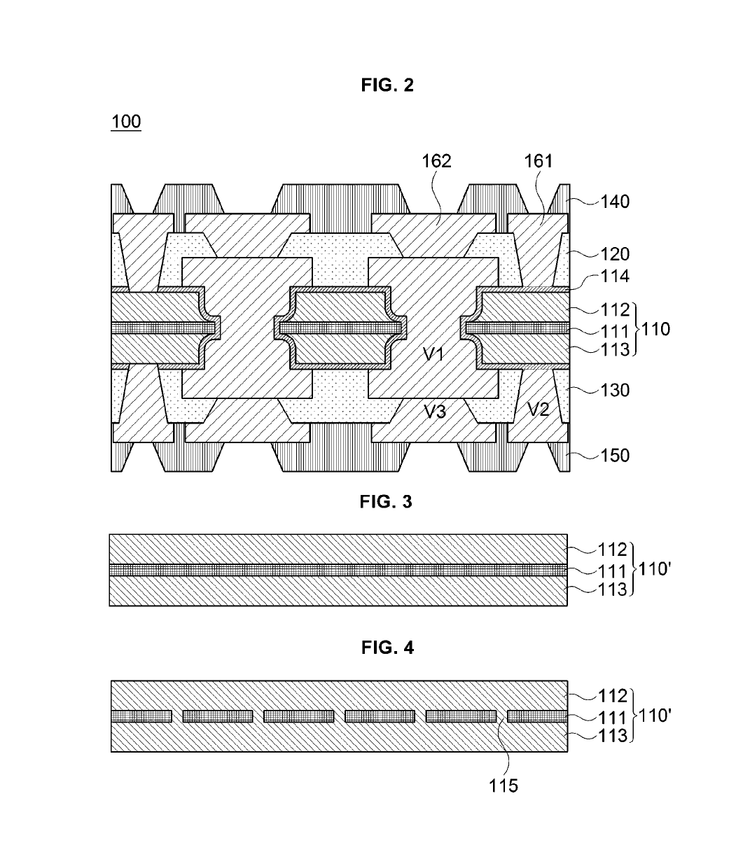

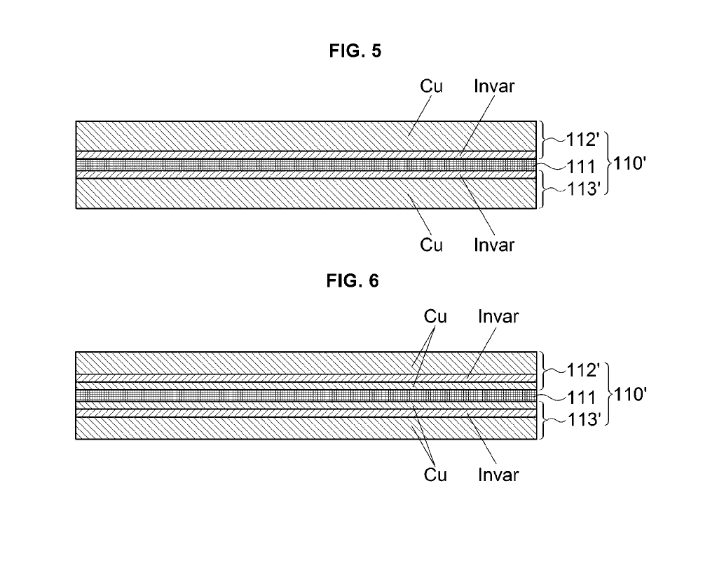

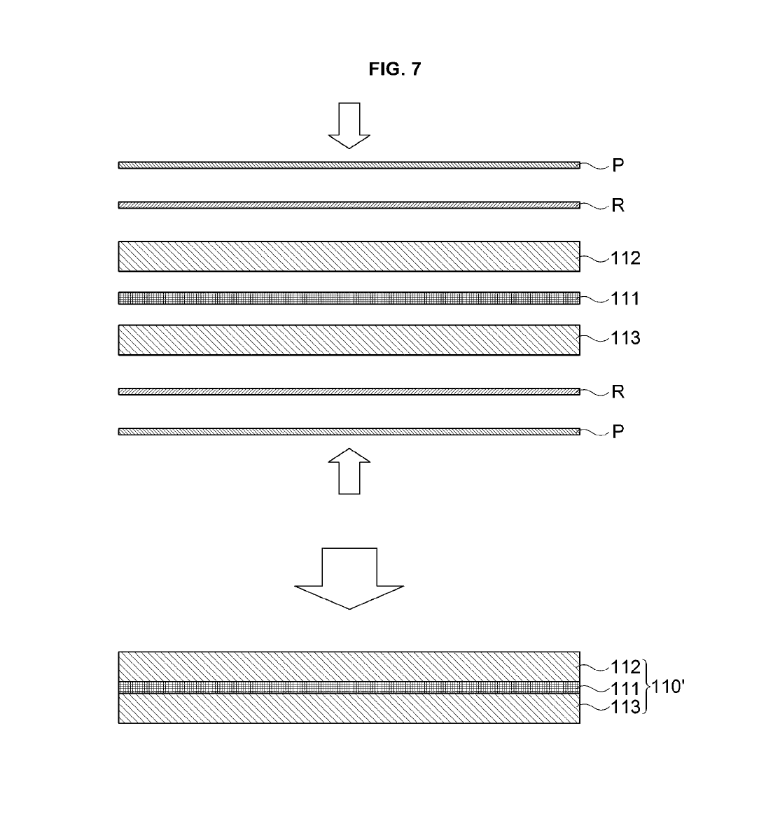

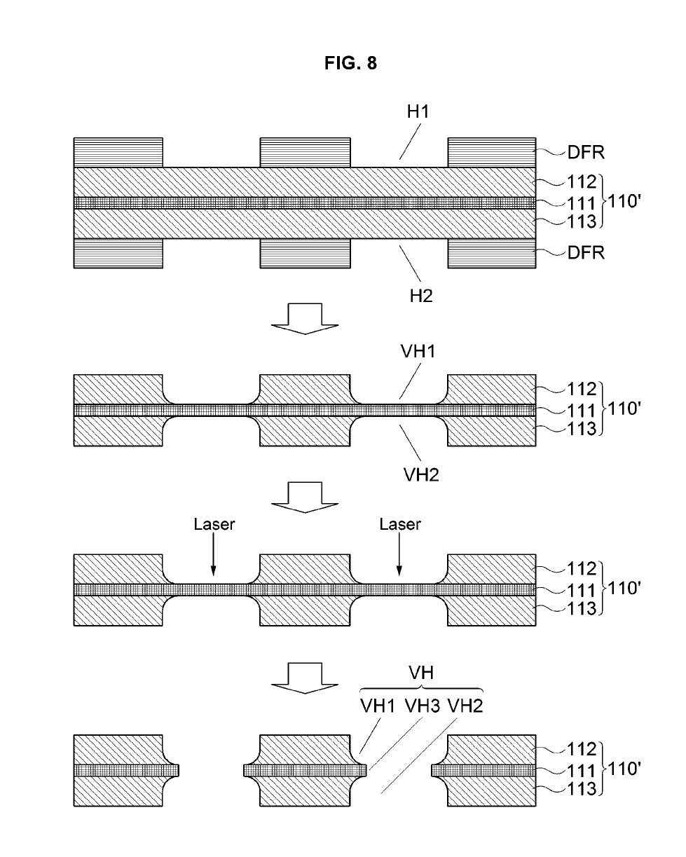

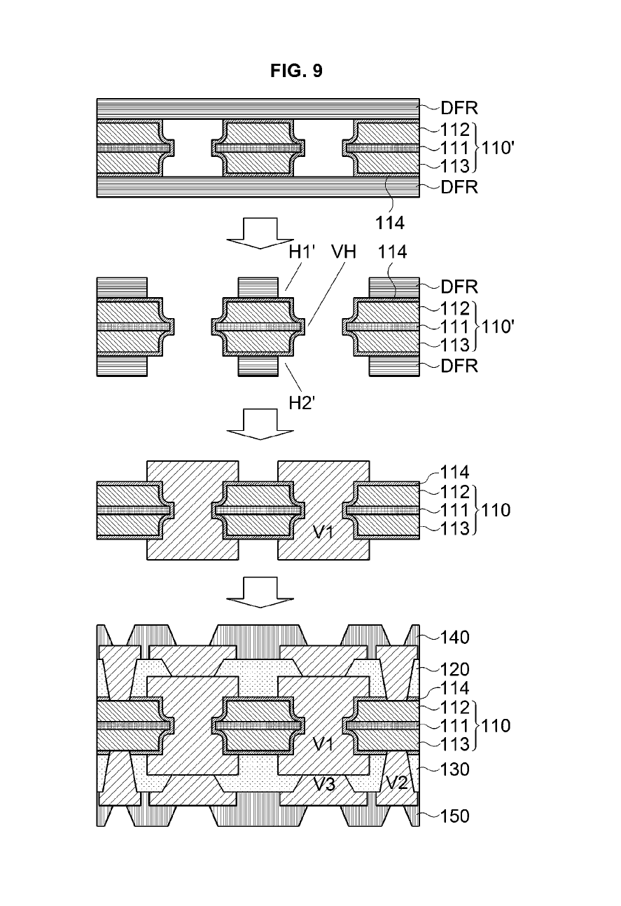

FIG. 1 is a diagram illustrating an example of a multilayered substrate 1000. FIG. 2 is a diagram illustrating an example of a circuit board 100. FIG. 3 is a diagram illustrating an example of a core portion 110′. FIG. 4 is a diagram illustrating an example of a core portion 110′. FIG. 5 is a diagram illustrating an example of a core portion 110′. FIG. 6 is a diagram illustrating an example of a core portion 110′. FIG. 7 and FIG. 8 are diagrams illustrating examples of some of the processes of forming the core portion 110′. FIG. 9 is a diagram illustrating an example of a method of manufacturing a circuit board.

Referring to FIG. 1 to FIG. 9, a circuit board 100 includes a core portion 110, and a first via V1 penetrating the core portion 110. In an example shown in FIG. 2, the core portion 110 may include a first core 112 and a second core 113, each of which is made of a metallic material. In another example, an insulation core 111 may be disposed between the first core 112 and the second core 113.

Moreover, in an example, the core portion 110 may have a first insulation layer 120 disposed on an upper surface thereof and a second insulation layer 130 on a lower surface thereof. A conductive pattern may be disposed on at least one of an upper surface of the first insulation layer 120 and a lower surface of the second insulation layer 130. Vias that penetrate the first insulation layer 120 or the second insulation layer 130 may also be provided.

A third insulation layer 140 may be disposed on the upper surface of the first insulation layer 120, and a fourth insulation layer 150 may be disposed on the lower surface of the second insulation layer 130. At least one of the third insulation layer 140 and the fourth insulation layer 150 may be a solder resist layer. The above-described conductive pattern may include a contact pad, and the contact pad being exposed to an outside through an opening of the solder resist layer. The contact pad being connected with an external device, such as, for example, an electronic component 200.

The contact pad may have a first contact pad 161 for heat transfer and a second contact pad 162 for transmission and reception of signals. If needed, the second contact pad 162 may also carry out the function of heat transfer. The first contact pad 161 may be in direct contact with a metallic material forming the core portion 110 through a second via V2, allowing the heat to be quickly transferred from an upper portion to a lower portion, or vice versa, of the circuit board 100.

The second contact pad 162 may be connected with the first via V1 through a third via V3. In an example, a surface of the core portion 110 and the first via V1 may be insulated from each other by an insulation film 114, and thus the second contact pad 162, the third via V3 and the first via V1 may be utilized as a path for transmission and reception of signals. Other insulation layers may be built up in addition to the first to fourth insulation layers 120, 130, 140, 150, without departing from the spirit and scope of the illustrative examples described.

In an example, the first via V1 may be formed in the general shape of an hourglass. The first via V1 may be formed in such a way that its diameter becomes narrower and then becomes wider again toward a bottom surface of the core portion 110 from a top surface of the core portion 110. A rate of reduction of the diameter of the first via V1 may be increased toward the bottom surface from the top surface of the core portion 110 and rapidly decreased near a center of the core portion 110. The diameter of the first via V1 may then be rapidly increased after a predetermined section before it is again decreased. In an example, as the core portion 110 may have the insulation core 111 interposed between the first core 112 and the second core 113, the reduction rate of diameter may be rapidly varied between the insulation core 111 and the first core 112 and between the insulation core 111 and the second core 113. The first via V1 may have a rate of change of diameter increased at a section of penetrating the first core 112, nearly unchanged at a section of penetrating the insulation core 111, and gradually decreased at a section of penetrating the second core 113, from the top surface toward the bottom surface of the core portion 110.

In an example, a via hole for forming the first via V1 may be provided by etching both surfaces of the core portion 110 by use of an etchant and then drilling a remaining portion to perforate the core portion 110. The drilling may be a mechanical drilling or a laser drilling, and for the sake of applying a fine drilling for the first via V1, it is more advantageous to use the laser drilling, which allows for a more precise processing.

In an example, the core portion 110 may include the insulation core 111, which is made of an insulation material. The first core 112 and the second core 113, which are made of a metallic material and are coupled to either surface of the insulation core 111.

The insulation core 111 may be made of an insulating material, such as, for example, polyimide, ABF, BT, PPG. The rigidity of the insulation core 111 may be enhanced by utilizing a fiberglass-impregnated insulation material. The heat dissipating performance of the insulation core 111 may be enhanced by utilizing graphite or graphene, which has a high thermal conductivity.

The first core 112 and the second core 113 may be made of copper, nickel, iron, cobalt, invar, or an alloy thereof. Referring to FIG. 5 and FIG. 6, in an example, two or three layers of copper and invar are laminated to form a first core 112′ and a second core 113′. In such a case, warpage may be mitigated by having the invar layers, which have a relatively low coefficient of thermal expansion, included in the core portion 110.

Referring to FIG. 7, the core portion 110′ may be formed by disposing the first core 112 and the second core 113 on either surface of the insulation core 110 and then compressing first core 112 and the second core 113 with a high pressure under a high temperature environment. A possible damage to the core portion 110′ that may occur while forming the core portion 110′ may be minimized, and the efficiency of the compression process may be enhanced, by applying a pressure to the first core 112 and the second core 113 after coupling release layers R to an outside surface of the first core 112 and an outside surface of the second core 113, respectively, and then coupling protective layers P to outside surfaces of the release layers R, respectively.

Referring to FIG. 8, a first via hole VH1 and a second via hole VH2 may be formed by forming a resist pattern having a first opening H1 and a second opening H2 on the core portion 110′ and then etching the core portion 110′. The etching process may be performed with an improved efficiency by using an etchant that selectively etches the metallic material of which the first core 112 and the second core 113 are made without etching the insulation material of which the insulation core 111 is made.

If the first via hole VH1 and the second via hole VH2 were formed without having the insulation core 111 disposed in the core portion 110, the physical property, exposure time and flow rate of the etchant would have to be precisely controlled in order to properly adjust a minimum distance between the first via hole VH1 and the second via hole VH2. In the etching process using the etchant that does not etch the insulation core 111, the minimum distance will be provided as thick as the insulation core 111 between the first via hole VH1 and the second via hole VH2 even if the etching process is performed with a lower level of precision than when the insulation core 111 is not disposed in the core portion 110. Since drilling the insulation material is more advantageous than drilling the metallic material in terms of speed and precision, the efficiency and precision of the process may be improved by having the first via hole VH1 and the second via hole VH2 connected with each other by drilling the insulation core 111, which is left after the etching process.

Forming a via hole having a predetermined depth through an etching process, the via hole may have a maximum diameter that is greater than the depth.

For a given thickness of a metallic core, the via hole will have a smaller maximum diameter when the via hole is formed by etching the core portion 110 partially from a first surface toward a second surface and by etching partially from the second surface toward a first surface, than when the via hole is formed by etching the core portion 110 only from one surface toward the other.

Therefore, the circuit board 100 described in the examples above allows for a reduced maximum diameter of the via penetrating the core portion 110 as well as an improved degree of integration of the via.

Referring to FIG. 4, in an example, the core portion 110 may include a heat dissipation pass 115, which penetrate the insulation core 111 and directly connects the first core 112 with the second core 113. The heat dissipation pass 115 may be made of a material having a high thermal conductivity, for example, a material having similar properties as those of the material forming the first core 112 and the second core 113, to improve a coefficient of heat transfer between the first core 112 and the second core 113. The heat dissipation pass 115 may be simultaneously formed with the first core 112 and the second core 113 by perforating the insulation core 111 at an area where the heat dissipation pass 115 is to be formed and then performing a plating process. Moreover, as described above, the insulation core 111 may be made of graphite or graphene, which normally forms a layer structure and has a relatively weak interlayer coherence. Accordingly, by disposing the described heat dissipation pass 115 while the insulation core 111 is provided with graphite or graphene having a weak interlayer coherence, bonding of the insulation core 111 itself or between the insulation core 111 and the first and second cores 112, 113 may be enhanced.

Referring to FIG. 2, in an example, the core portion 110 may have the insulation film 114 disposed on its surface. By forming the insulation film 114 with a vapor deposition method, a thickness of the insulation film 114 may be precisely controlled. Accordingly, it is possible to provide sufficient insulation with a minimized decrease of heat transfer performance of the core portion 110.

Referring to FIG. 8 and FIG. 9, following processes may be carried out using the core portion 110 that includes a core via hole VH constituted with the first via hole VH1, the second via hole VH2 and a third via hole VH3. After forming a resist DFR on the core portion 110, a first opening H1′ and a second opening H2′ are formed in an upper portion and a lower portion of the core via hole VH, respectively.

The first via V1 may be formed by filling in a conductive material inside the core via hole VH through the first opening H1′ and the second opening H2′.

Accordingly, by using the core portion 110 having the first via V1 formed therein as described above, the circuit board 100 including the core may be manufactured by carrying out general processes of manufacturing a circuit board.

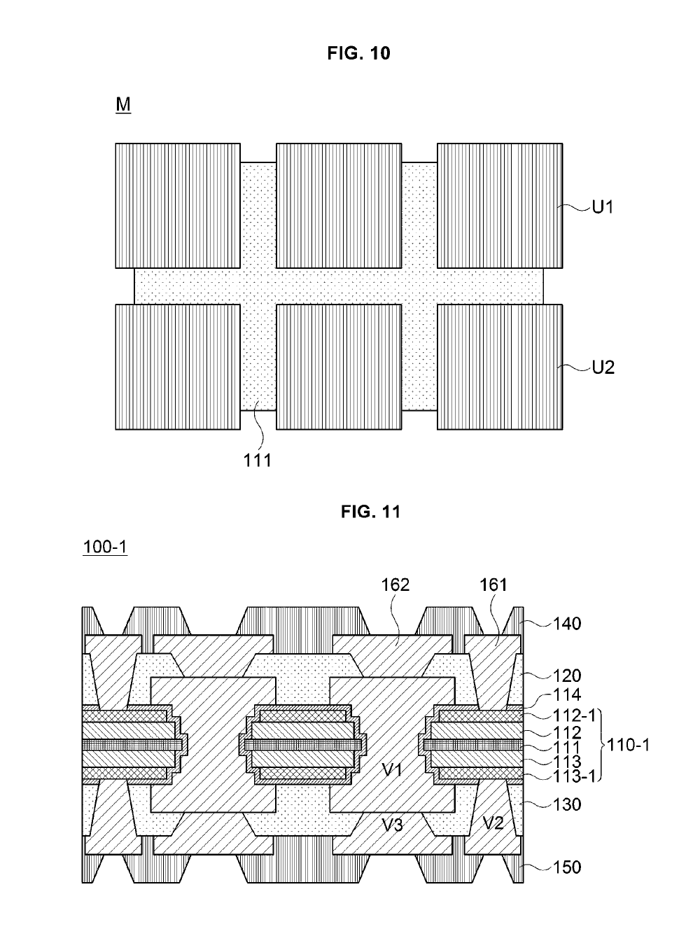

FIG. 10 is a diagram illustrating an example of a module M for unilateral manufacture of a plurality of circuit boards.

In an example, one unit U1 of a circuit board having a core therein may be manufactured through a unilateral process while being connected with another unit U2, thereby possibly improving a rate of manufacture per hour.

The units U1 and U2 may be manufactured as the module M first and may be given various electrical tests, such as, for example, an insulation test, a conduction test, before being separated into the units U1 and U2.

As the electrical tests need to be individually performed for the units U1 and U2, units U1 and U2 need to be electrically insulated from each other. Here, in the above-described example in which the core portion 110 includes the insulation core 111, the first core 112 and the second core 113, the units U1, U2 may be maintained in the form of module M while still being insulated from each other, by removing the first core 112 and the second core 113 at a boundary between the units U1 and U2 and leaving the insulation core 111. Accordingly, it is possible to improve the efficiency of the electrical tests and reduce a possible test error.

FIG. 11 is a diagram illustrating an example of a circuit board.

Referring to FIG. 11, a core portion 110-1 may further include a first additional core 112-1 and a second additional core 113-1.

For instance, an insulation core 111 may have a first core 112 and a second core 113, both of which are made of a first metal, formed on external surfaces of the insulation core 111. The first core 112 and the second core 113 may have the first additional core 112-1 and the second additional core 113-1, both of which are made of a second metal, formed on external surfaces of the first core 112 and the second core 113, respectively.

The first metal and the second metal may be different kinds of metals. For example, the first metal may be invar, and the second metal may be copper. Accordingly, while etching the core portion 110-1, a step difference may be formed between the first additional core 112-1 and the first core 112. Moreover, while etching the core portion 110-1, a step difference may be formed between the second additional core 113-1 and the second core 113. As a result, it is possible to reduce a void from occurring during a plating process.

Moreover, the core portion 110-1 may allow the efficiency of forming the via hole to be improved, compared to forming the core portion using only one metallic material, such as invar, having a relatively higher rigidity. Moreover, the core portion 110-1 may have an increased rigidity and hence an improved warpage mitigation effect compared to the core portion formed using a metallic material, such as copper, having a relatively lower rigidity.

Similar to the earlier description, the first via V1 may be formed by applying laser drilling or mechanical drilling to perforate a via hole in the insulation core 111.

In addition, it is possible that the number of wiring layers disposed on one side of the core portion is different from the number of wiring layers disposed on the other side of the core portion. In order to mitigate the warpage problem, the number of layer on an upper surface of the core has been conventionally the same as the number of layers on a lower surface of the core. However, as the rigidity of the core portion disposed in the circuit board may be enhanced compared to the conventional core portion, the warpage problem may be mitigated even though the build-up layers or wiring layers are asymmetrically disposed above and below the core portion.

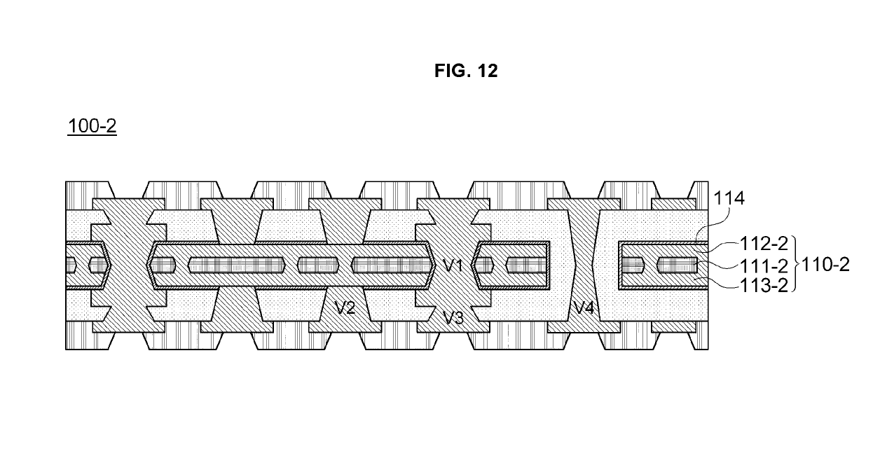

FIG. 12 is a diagram illustrating an example of a circuit board.

Referring to FIG. 12, a core portion 110-2 may have a second metal core 112-2 formed on one surface of a first metal core 111-2 and a third metal core 113-2 formed on the other surface of the first metal core 110-2. The second metal core 112-2 and the third metal core 113-2 may be made of a same material, and the first metal core 111-2 may be made of a material that is different from that of the second metal core 112-2 and the third metal core 113-2.

For instance, the first metal core 111-2 may be made of invar, and the second metal core 112-2 and the third metal core 113-2 may be made of copper. Accordingly, the core portion 110-2 may have an improved efficiency of forming the via hole, compared to when the core portion is formed using a metallic material, such as invar, having a relatively higher rigidity only. Moreover, the core portion 110-2 may have an increased rigidity and hence an improved warpage mitigation effect compared to when the core portion is formed using a metallic material, such as copper, having a relatively lower rigidity.

Similar to the earlier description, a first via V1 may be formed by performing an etching process to perforate a via hole in the core portion 110-2.

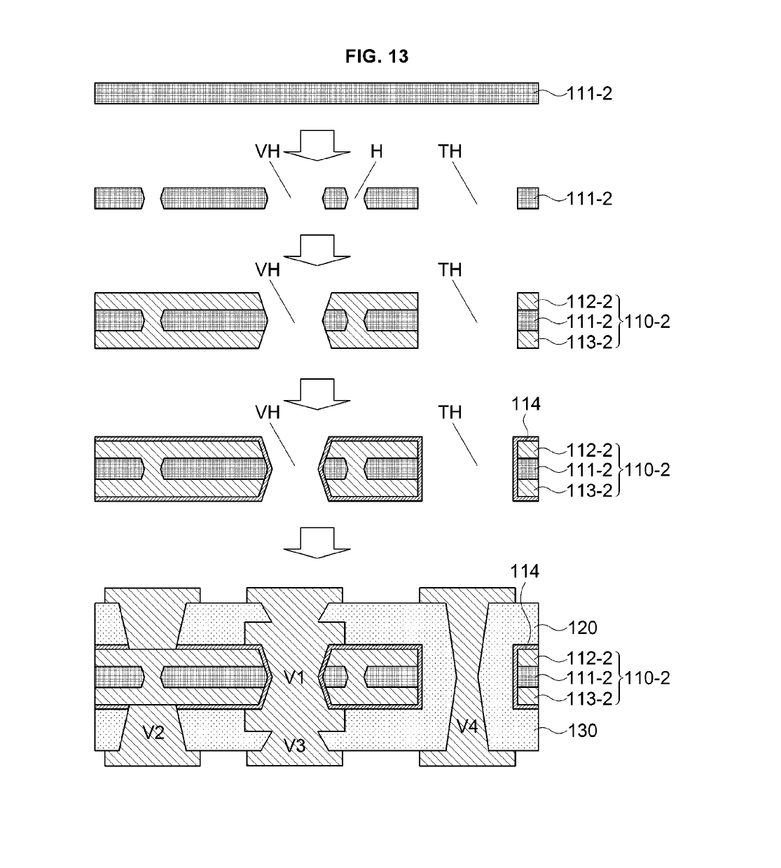

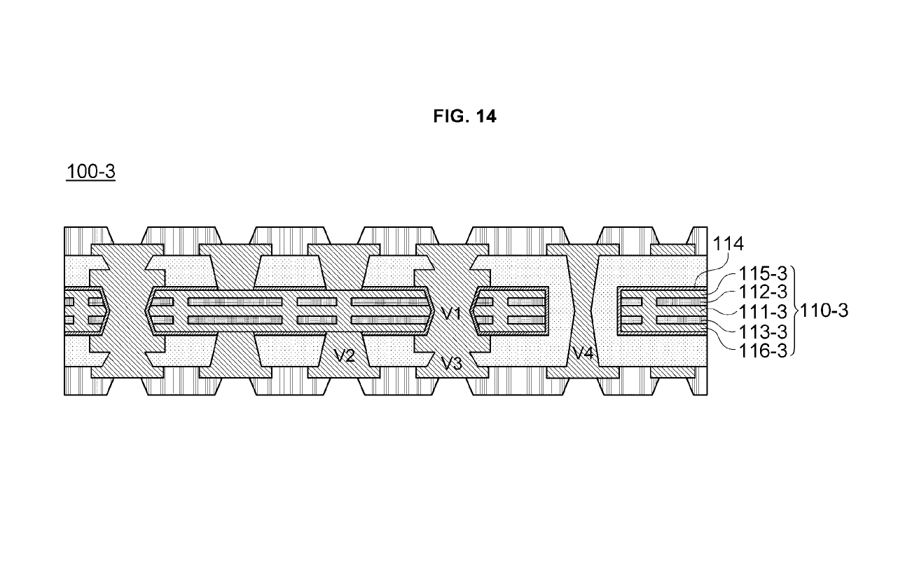

Referring to FIG. 13, in another example, a hole H penetrating the first metal core 111-2 may be provided, and a metallic material forming the second metal core 112-2 and the third metal core 113-2 may be filled inside the hole H. Accordingly, although the first metal core 111-2 is made of a different metal from those of the second metal core 112-2 and the third metal core 113-2, bonding between the first metal core 111-2 and the second and third metal cores 112-2, 113-2 may be enhanced.

Moreover, in yet another example, a through-hole TH penetrating the core portion 110-2 may be provided. A first insulation layer 120 and a second insulation layer 130 may be formed by providing an insulation material above and below the core portion 110-2, respectively. The insulation material provided above and below the core portion 110-2 is filled inside the through-hole TH as well. A fourth via V4 penetrating the insulation material filled in the through-hole TH may be formed. Since a via hole can be perforated in the insulation material more quickly and easily than forming a via hole in the core portion 110-2 made of a metallic material, the fourth via V1 may be formed more efficiently. Furthermore, insulation between the fourth via V1 and the core portion 110-2 may be improved when compared to insulation provided through an insulation film 114 only.

FIG. 13 is a diagram illustrating an example of some of the processes of manufacturing the circuit board shown in FIG. 12.

Hereinafter, the processes of forming the core portion 110-2 will be described with reference to FIG. 13. The hole H and the through-hole TH are formed in the first metal core 111-2 that is made of a metallic material, such as, for example, invar. The hole H may be formed using an etching process, and the through-hole TH may be formed using a drilling process. The second metal core 112-2 and the third metal core 113-2 may be formed with a metallic material, such as, for example, copper. By filling the copper inside the hole H as well, the second metal core 112-2 and the third metal core 113-2 may be connected with each other, thereby improving the bonding between the first metal core 111-2 and the second and third metal cores 112-2 and 113-2. If needed, the insulation film 114 may be formed on an exposed surface of the core portion 110-2. For instance, the insulation film 114 may be formed on an upper surface of the second metal core 112-2, a lower surface of the third metal core 113-2 and an inner wall of the through-hole TH.

Then, the first insulation layer 120 and the second insulation layer 130 may be formed by disposing an insulation material on an upper surface and a lower surface of the core portion 110-2. The insulation material may be filled inside the through-hole TH as well.

A second via V2 penetrating each of the first insulation layer 120 and the second insulation layer 130 may be formed. A fourth via V4 penetrating both the first insulation layer 120 and the second insulation layer 130 may be formed. A circuit pattern may be formed on an upper surface of the first insulation layer 120 or on the second insulation layer 130. In FIGS. 12 and 13, it is shown that the second via V2 is in contact with the core portion 110-2 by penetrating the first insulation layer 120 or the second insulation layer 130 and the fourth via V4 penetrates an inside of the through-hole TH and the first and second insulation layers 120 and 130. In an example, the second via V2 may perform the function of transferring heat, and the fourth via V4 may perform the function of transferring at least a signal. In another example, the fourth via V4 may transfer a signal only or transfer the heat with the signal. When the insulation film 114 is formed on the core portion 110-2, the second via V2 is allowed to be in direct contact with the second core 112-2 or the third core 113-2 by penetrating the insulation film 114 to further improve the heat transfer and heat dissipation performances. The first via V1 and the third via V3 have been described above, and is incorporated herein by reference. Thus, the above description may not be repeated here.

FIG. 14 is diagram illustrating an example of a circuit board.

Referring to FIG. 14, a core portion of 110-3 may be constituted with a first metal core 111-3, a second metal core 112-3, a third metal core 113-3, a fourth metal core 115-3, and a fifth metal core 116-3.

The first, fourth and fifth metal cores 111-3, 115-3, 116-3 may be made of a one material, and the second and third metal cores 112-3, 113-3 may be made of a another material. For instance, the first, fourth and fifth metal cores 111-3, 115-3, 116-3 may be made of a material such as, for example, copper. The second and third metal cores 112-3, 113-3 may be made of a material such as, for example, invar.

In another example, a hole H penetrating the second metal core 112-3 and a hole penetrating the third metal core 113-3 may be provided. The metallic material constituting the first metal core 111-3, the fourth metal core 115-3, and the fifth metal core 116-3 may be filled inside the holes H. Although the first, fourth and fifth metal cores 111-3, 115-3, 116-3 and the second and third metal cores 112-3, 113-3 are made of different kinds of metals, coherence between the first to fifth metal cores 111-3, 112-3, 113-3, 115-3, 116-3 may be enhanced.

In yet another example, a first insulation layer 120 and a second insulation layer 130 may be formed on a surface of the core portion 110-3 while a through-hole TH penetrating the core portion 110-3 is provided. Accordingly, a fourth via V4 penetrating an insulation material filled in the through-hole TH may be formed more efficiently, and insulation between the fourth via V4 and the core portion 110-3 may be further enhanced.

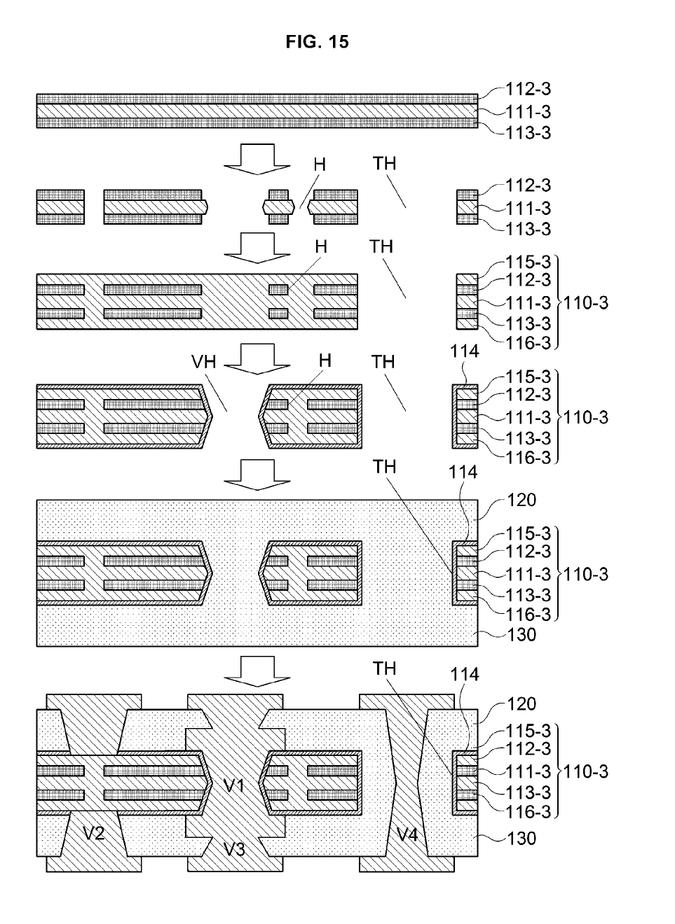

FIG. 15 is a diagram illustrating an example of some of the processes of manufacturing the circuit board shown in FIG. 14.

Hereinafter, the an example of the processes of forming the core portion will be described with reference to FIG. 15. The second metal core 112-3 and the third metal core 113-3 made of invar are disposed on either surface of the first metal core 111-3 made of copper. The hole H may be formed, for example, by etching, and the through-hole TH may be formed, for example, by mechanical or laser drilling.

The fourth metal core 115-3 and the fifth metal core 116-3 may be formed by performing a plating process with a material, such as, for example, copper.

Filling the inside the hole H with a material, such as, for example, copper, assists in connecting the first metal core 111-3 with the fourth metal core 115-3 and the fifth metal core 116-3, resulting in an improved coherence between the first to fifth metal cores 111-3, 112-3, 113-3, 115-3, and 116-3. An insulation film 114 may be formed on an exposed surface of the core portion 110-3. For instance, the insulation film 114 may be formed on an upper surface of the fourth metal core 115-3, a lower surface of the fifth metal core 116-3 and an inner wall of the through-hole TH.

The first insulation layer 120 and the second insulation layer 130 may be formed by disposing insulation resin on an upper surface and a lower surface of the core portion 110-3. The insulation resin may also be filled inside the through-hole TH.

A second via V2 may be formed by penetrating each of the first insulation layer 120 and the second insulation layer 130. A fourth via V4 is formed by penetrating the first insulation layer 120 and the second insulation layer 130 altogether. A circuit pattern may be formed on an upper surface of the first insulation layer 120 or on the second insulation layer 130. As illustrated in FIGS. 14 and 15, the via in contact with the core portion 110-2 by penetrating the first insulation layer 120 or the second insulation layer 130 is indicated as the second via V2 and that the via penetrating an inside of the through-hole TH and the first and second insulation layers 120, 130 is indicated as the fourth via V4. The second via V2 may perform the function of transferring heat, and the fourth via V4 may perform the function of transferring at least a signal. The fourth via V4 may transfer a signal only or transfer the heat with the signal. When insulation film 114 is formed on the core portion 110-3, the second via V2 may be in direct contact with the fourth core 115-3 or the fifth core 116-3 by penetrating the insulation film 114 to further improve the heat transfer and heat dissipation performances.

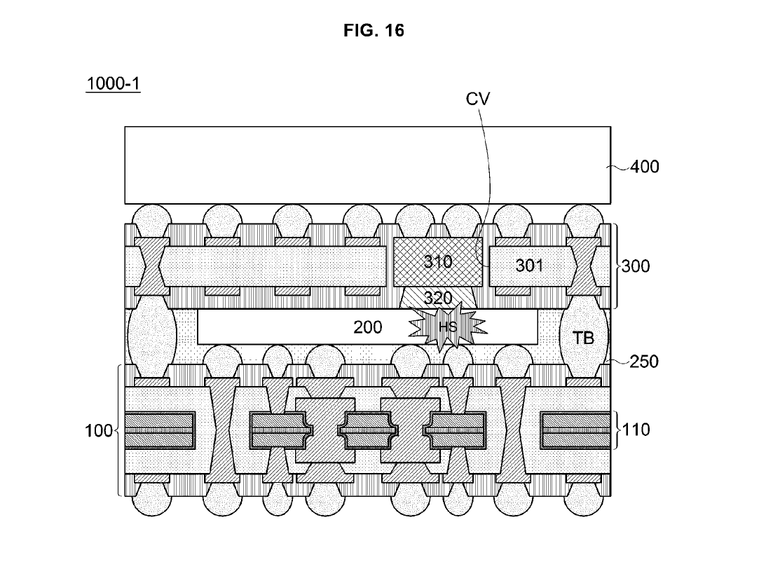

FIG. 16 is a diagram illustrating an example of a multilayered substrate.

Referring to FIG. 1 and FIG. 16, a multilayered substrate 1000, 1000-1 may include an electronic component 200 and an interposer 300.

The electronic component 200, which is coupled to the above-described circuit board 100, may be mounted on a surface of the circuit board 100 or may be embedded in the circuit board 100 by having at least a portion thereof inserted in the circuit board 100. The electronic component 200 may be an active device, for example, an integrated circuit, and the temperature of the electronic component 200 may be elevated when the electronic component 200 is operated. In an example, the electronic component 200 may include so-called a hot spot HS, of which the temperature becomes higher than other regions of the electronic component 200.

An additional substrate 400 may be disposed above the circuit board 100 and the electronic component 200, and an additional means 300 for connecting the additional substrate 400 with the circuit board 100 may be provided. The interposer 300 typically refers to the aforementioned means.

Referring to FIG. 16, the interposer 300 included in the multilayered substrate 1000-1 may include a heat transferring structure 310 made of a thermally conductive material, such as, for example, copper. The heat transferring structure 310 may have a greater volume than a typical via and thus may have the heat of the electronic component 200, particularly the hot spot HS, transferred thereto and moved to another region quickly, thereby preventing a malfunction or damage from occurring in the electronic component 200.

The above-described circuit board 100 may also achieve the dual effects of improvement of heat transfer performance and mitigation of warpage problem, by implementing the core portion with a metallic material. While the heat generated by the electronic component 200 may be quickly dissipated through the circuit board 100, the warpage problem of the circuit board 100 itself may be mitigated. Furthermore, the interposer 300 possibly disposed above the electronic component 200 may also have a means for dissipating the heat of the electronic component. In the present example, by having the heat transferring structure 310 included in the interposer 300, the heat dissipation of the electronic component 200 may be further facilitated. The heat transferring structure 310 and the electronic component 200 may be interconnected with each other by way of a coupling member 320. In an example, the coupling member 320 may be implemented with a typical solder ball. In another example, the coupling member 320 is implemented with a material having a high thermal conductivity than the solder ball, for example, copper, to improve the heat dissipation performance. In an example, the interposer 300 may also include a core 301, and the heat transferring structure 310 may be inserted into a cavity CV disposed in the core 301.

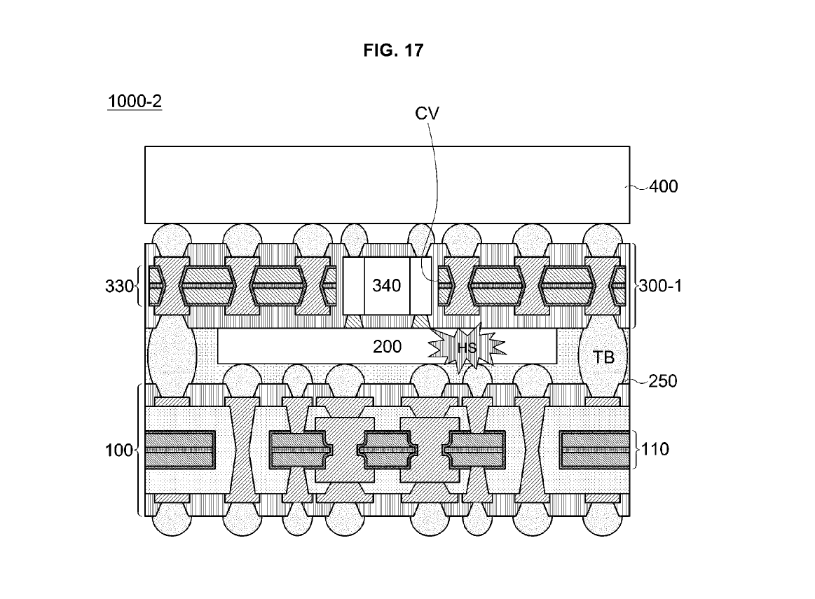

FIG. 17 is a diagram illustrating an example of a multilayered substrate.

Referring to FIG. 17, an interposer 300-1 included in a multilayered substrate 1000-2 may be configured in a similar structure as that of the above-described circuit board 100. The interposer 300-1 may include a core portion 330 made of a first metal and a second metal.

As illustrated in FIG. 17, the core portion 330 may have a cavity CV formed therein, and the cavity CV may have a device 340, for example, an MLCC.

Heat may be dissipated above an electronic component 200, and furthermore, connection between the electronic component 200 and the device 340 such as an MLCC may be shortened, possibly improving a signal transfer speed or a power stabilization speed.

The aforementioned device 340 may be a decoupling capacitor, in which case it is advantageous for reduction of power noise of the electronic component 200.

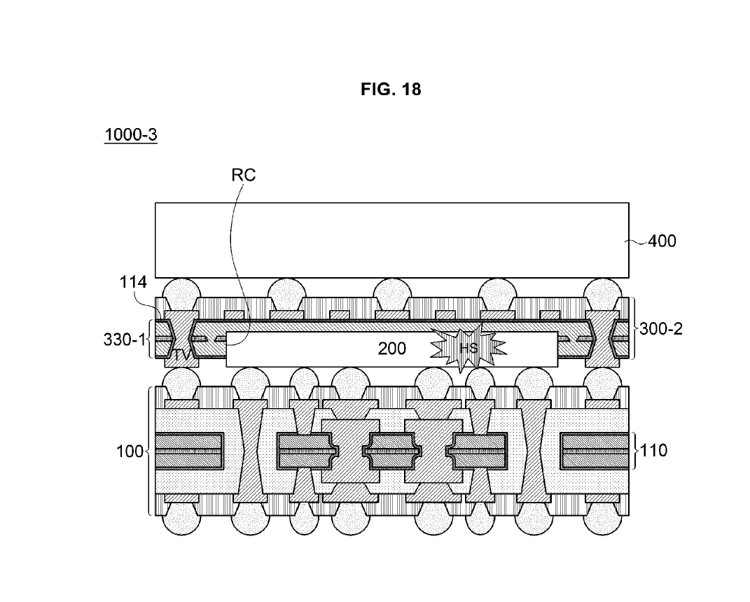

FIG. 18 is diagram illustrating an example of a multilayered substrate.

Referring to FIG. 18, an interposer 300-2 is included in a multilayered substrate 1000-3 may include a core portion 330-1 having a recess portion RC. The shape of the recess portion RC may correspond to an electronic component 200, and at least a portion of the electronic component 200 may be inserted into the recess portion RC. Moreover, in the present example, the core portion 330-1 may be made of a metallic material and, in an example may be constituted with first to third metal cores, each made of a different metal.

Accordingly, at least a portion of an external surface of the electronic component 200 may be in direct contact with the metallic core portion 330-1, possibly resulting in speedy dissipation of heat generated by the electronic component 200 through the core portion 330-1.

If insulation is required on a surface contacted between the electronic component 200 and the core portion 330-1, the above-described insulation film 114 may be provided.

While the examples illustrated in FIG. 16 and FIG. 17 have a molding portion 250 filled in between the circuit board 100 and the interposer 300, 300-1, the present example may not have the molding portion 250 included therein because the interposer 300-2 itself is capable of covering at least a portion of the electronic component 200.

Moreover, in the examples illustrated in FIG. 16 and FIG. 17, a top ball TB, which has a different height from other solder balls, is commonly disposed for electrical connection between the circuit board 100 and the interposer 300, 300-1. However, in the present example, the top ball TB (see FIG. 16 and FIG. 17) may be substituted by a through-via TV penetrating the core portion 330-1. Generally, the greater the distance between two terminals connected by a solder ball, the diameter of the solder ball increases. However, since the top ball TB, which is a kind of solder ball, may be substituted by the through-via TV in the present example, the area of a contact pad may be reduced, and thus the pitch of the contact pad may become finer.

Meanwhile, the aforementioned insulation film 114 may be also disposed on an interface between the through-via TV and the core portion 330-1.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A circuit board comprising:
a core portion comprising a first core and a second core made of a metallic material, the first core and the second core being disposed adjacent to each other; and
a first via penetrating the core portion.

2. The circuit board of claim 1, wherein the first via is formed in the shape of an hourglass.

3. The circuit board of claim 1, wherein the core portion further comprises an insulation core made of an insulation material, and wherein:
the first core is disposed on a first surface of the insulation core, and
the second core is disposed on a second surface of the insulation core.

4. The circuit board of claim 3, wherein a rate of change of diameter of the first via increases as the first via penetrates the first core, remains constant as the first via penetrates the insulation core, and decreases as the first via penetrates the second core.

5. The circuit board of claim 3, wherein the insulation core is made of graphite or graphene.

6. The circuit board of claim 3, further comprising a heat dissipation pass penetrating the insulation core and connecting the first core with the second core.

7. The circuit board of claim 1, wherein an insulation film is disposed on an interface between the core portion and the first via.

8. The circuit board of claim 7, further comprising a second via penetrating the insulation film and being in contact with a surface of the core portion.

9. The circuit board of claim 8, wherein an electric signal passes through the first via and a heat passes through the second via.

10. The circuit board of claim 1, wherein the core portion comprises:
an insulation core interposed between the first core and the second core and made of an insulation material;
a first additional core made of a different metallic material from that of the first core and the second core and disposed on a surface of the first core; and
a second additional core made of a different metallic material from that of the first core and the second core and disposed on a surface of the second core.

11. The circuit board of claim 10, wherein a step difference is formed at an interface of the first core and the first additional core.

12. The circuit board of claim 10, wherein the first core and the second core are made of invar, and
wherein the first additional core and the second additional core are made of copper.

13. The circuit board of claim 1, further comprising:
a through-hole penetrating the core portion and filled with insulation resin; and
a fourth via penetrating the insulation resin.

14. A circuit board comprising:
a first core made of a first metallic material;
a second core made of a different metallic material from the first metallic material and having a surface in contact with a first surface of the first core;
a third core made of a different metallic material from the first metallic material and having a surface in contact with the a second surface of the first core; and
a first via penetrating from a surface of the second core not in contact with the first core to a surface of the third core not in contact with the first core.

15. The circuit board of claim 14, wherein a hole penetrates the first core, and a material of the second core or the third core is filled in the hole.

16. The circuit board of claim 14, wherein an insulation film is formed to separate the first, second and third cores from the first via.

17. The circuit board of claim 14, further comprising:
a through-hole penetrating from a surface opposing the surface of the second core to a surface opposing the surface of the third core and having insulation resin filled therein; and
a fourth via penetrating the insulation resin inside the through-hole.

18. The circuit board of claim 14, wherein the first core is made of invar, and the second core and the third core are made of copper.

19. A circuit board comprising:
a first core made of a first metallic material;
a second core made of a different metallic material from the first metallic material and having the a surface in contact with a first surface of the first core;
a third core made of a different metallic material from the first metallic material and having a surface in contact with a second surface of the first core;
a fourth core made of the first metallic material and having a surface in contact with a surface opposing the surface of the second core;
a fifth core made of the first metallic material and having a surface in contact with a surface opposing the surface of the third core; and
a first via penetrating from a surface of the fourth core not in contact with the second core to a surface of the fifth core not in contact with the third core.

20. The circuit board of claim 19, wherein a hole penetrates the first core, and a material of the second core or the third core is filled in the hole.

21. The circuit board of claim 19, wherein an insulation film is formed to separate the first, second, third, fourth and fifth cores from the first via.

22. The circuit board of claim 19, further comprising:
a through-hole penetrating from the a surface opposing the surface of the fourth core to a surface opposing other surface of the fifth core and having insulation resin filled therein; and
a fourth via penetrating the insulation resin inside the through-hole.

23. A method of manufacturing a circuit board as set forth in claim 1, comprising:
providing the core portion;
etching the core portion from one surface toward the other surface; and
etching the core portion from the other surface toward the one surface thereof.

24. The method of claim 23, wherein the core portion comprises an insulation core, and
wherein the method further comprises drilling the insulation core.

25. A multilayered substrate comprising:
a circuit board as set forth in claim 1; and
an electronic component disposed above the circuit board and being connected to at least the first via.

26. The multilayered substrate of claim 25, further comprising an interposer being connected to the circuit board and disposed above the electronic component.

27. The multilayered substrate of claim 26, wherein the interposer comprises a heat transferring structure made of a thermally conductive material.

28. The multilayered substrate of claim 26, wherein a capacitor is embedded in the interposer.

29. The multilayered substrate of claim 26, wherein the interposer has a same structure as that of the circuit board as set forth in claim 1.

30. The multilayered substrate of claim 25, further comprising an interposer having a recess, the recess having at least a portion of the electronic component inserted therein.

31. The multilayered substrate of claim 30, further comprising a through-via penetrating a core portion of the interposer,
wherein a distance from a bottom surface of the through-via to a top surface of the circuit board is shorter than a distance from a top surface of the electronic component to the top surface of the circuit board.
